(19) United States
(12) Patent Application Publication
(10) Pub. No.: US 2003/0085827 A1
(43) Pub. Date: May 8, 2003

(54) Apparatus and method for dynamic element matching

(76) Inventors: Vladimir Koifman, Rishon-Lezion (IL); Yachin Afek, Kfar Saba (IL)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/085,015

(22) Filed: Feb. 28, 2002

(30) Foreign Application Priority Data
Nov. 6, 2001 (GB) 0126567.7

(51) Int. Cl. H03M 1/66; H03M 3/00

(52) U.S. Cl. 341/144; 341/143

(57) ABSTRACT

Apparatus and method of dynamic element matching overcomes problems associated with noise arising from mismatch errors thereby enabling high quality devices and systems to be made from cheaper, low tolerance components.

An input signal has a transfer function applied thereto so as to transform its value. A plurality of predetermined values are accessed, from a digital store and are added together. Information derived from the transformed value is compared with the simulation of the predetermined values so as to derive an error signal. The error signal is used to correct signal mismatch.

### BACKGROUND

The present invention relates to an apparatus and method for dynamic element matching.

The invention is particularly, though not exclusively, suitable for dynamic matching of elements in a system where a sum of N equal signal sources are required to be used from a possible M signals, where N is less than or equal to M. An example of such a system is a Digital-to-Analog Converter (DAC) incorporating an over sampled Sigma-Delta conversion method. An element may be an electronic component such as a capacitor or a current source.

One of the noise sources in DAC's arises from variation in component values and may be attributable to variations arising from the manufacturing process or thermal drift during operation of a device. Such noise arises principally as result of mismatch of values, for example such as capacitors. One way of overcoming this noise is to impose higher tolerances on the manufacture of components. However, this tends to decrease yield and therefore increases costs of unit components.

In the past one way of solving the problem of element mismatch was to use dynamic matching algorithms. Generally however, the algorithms had limited Signal to Noise Ratio properties and a limited dynamic range.

### PRIOR ART

Over sampling Sigma-Delta converters are prevalent in many electronic devices, as they are required in many different types of high-resolution Digital-to-Analog converters. Multi-bit Sigma-Delta converters have much better stability than single-bit ones. However, a disadvantage has been that multi-bit DAC's need to incorporate precise components, such as current sources, in order to be as linear as possible, across as broad a spectrum as possible.

An example of a simple version of a dynamic matching algorithm is shown diagrammatically in FIG. 1. A randomizer couples one input line to one output line in a random way. The order of coupling input and output lines changes with each clock cycle.

The aforementioned randomizer influence is expressed as noise having a constant spectral density up to half of the Nyquist sampling frequency. The low pass filter removes any high frequency mismatch noise. However, some signal mismatch still occurs and this may not be acceptable in systems, which demand very high performance.

Reported simulation results, by RT Baird and TS Fiez, in Proceeding of IEEE International Symposium on Circuits and Systems, Vol. 1 at pages 13-16, May 1995, indicate that element mismatch errors in a multi-bit Digital-to-Analog Converter (DAC), comprising unit elements, can be noise-shaped. A related work, published in the aforementioned Proceedings, at pages 17-20, shows an example of first-order Noise-Shaping.

An example of a dynamic matching technique is described in IEEE Journal of Solid State Circuits Vol. 24, Issue 2 Aril 1989 at page 267, in an Article entitled: “A Noise Shaping Coder Topology for 15+ bit Converters”, by L R Carley.

Another example of an existing arrangement is shown diagrammatically in FIG. 2. The arrangement in FIG. 2 shapes signal mismatch noise in such a way that most of the noise is outside the desired bandwidth. The method of noise shaping is operated each clock cycle and uses existing components of analog array elements. The number of elements used in each clock cycle is defined by the value of the input signal. After using the elements in the array, elements are used again. This recycling process continues and has improved the Signal-to-Noise ratio (SNR).

However, in the arrangement depicted in FIG. 2, mismatch noise is shaped in such a way that the spectral density of the noise rises with frequency. A problem has been to achieve a high integral level of linearity, whilst still reducing any overall harmonic distortion that may occur.

The present invention arose in order to decrease the aforementioned problems impact on the performance and to provide an improved method of Dynamic Element Matching.

### SUMMARY OF THE INVENTION

According to a first aspect of the present invention there is provided an apparatus for dynamic element matching comprising: means for receiving an input, means for applying a transfer function for transforming the input to a transformed value; a store containing a plurality of predetermined values which are accessible in digital form; means for retrieving one or more of the stored values in accordance with an instruction derived from the transformed value; an adder for summing retrieved stored values and providing, in digital form, an output of the sum of said values; means for comparing said sum with the transformed value so that an error signal is derived, wherein said error signal is used to correct any signal mismatch.

Additionally means may be provided to modify the order of the transfer function so that an optimisation of element matching is achieved. For example, components performing logical operations such as inverters or AND gates may be used to achieve change the order of a transfer function.

Accordingly most of the noise is concentrated at higher frequencies. An advantage of this is that it improves the Signal-to-Noise Ratio in the frequency band of interest.

Use of the invention ensures that any mismatch noise is minimised and that spectral density of mismatch noise is proportional to the square, or higher order degree, such as cube or fourth power, of frequency.

The invention may be incorporated in high precision Digital-to-Analog Converters (DAC's) or Analog-to-Digital Converters (ADC's). These ADC's and DAC's may be included in telecommunication equipment, such as cellular telephones and other systems and devices requiring high precision measurement; such as for example devices in the automotive and medical fields.

A particular advantage of the invention is that the operation of multi-bit converters is vastly improved: they have better Signal-to-Noise ratio (SNR) and their linearity is greatly improved.

It has been found that by using the present invention very high-resolution converters can be built using relatively cheap components and a readily available process.

According to another aspect of the present invention there is provided a method for dynamic element matching comprising: the steps of receiving an input, applying a transfer function which transforms the input to a transformed value; accessing a store containing a plurality of predetermined values and retrieving one or more of the stored values in digital form, in accordance with an instruction derived from the transformed value; summing retrieved stored values and providing, in digital form, an output of the sum; comparing said sum with the transformed value so that an error signal is derived; and using said error signal to correct signal mismatch.

### BRIEF DESCRIPTION OF THE DRAWINGS

Preferred embodiments of the invention will now be described with reference to the Figures in general, and particular reference to FIG. 3, in which:

FIG. 1 is a diagrammatical overview of how random switching occurs in the PRIOR ART;

FIG. 2 is another example of a PRIOR ART system;

FIG. 3 is a diagrammatical representation of an embodiment of the Invention;

FIG. 4 is an example of H(z) implementation for second-order shaping;

FIG. 5 shows a simulation of results obtained by using the Invention;

FIG. 6 is an overall block diagram view of a single-quantizer Delta-Sigma modulator;

FIG. 7 is a general view of a second-order modulator;

FIG. 8 is a modified general second-order modulator; and

FIG. 9 is an example of a noise-shaped Digital to Analog Convertor.

### DETAILED DESCRIPTION OF THE PREFERRED EMBODIMENT

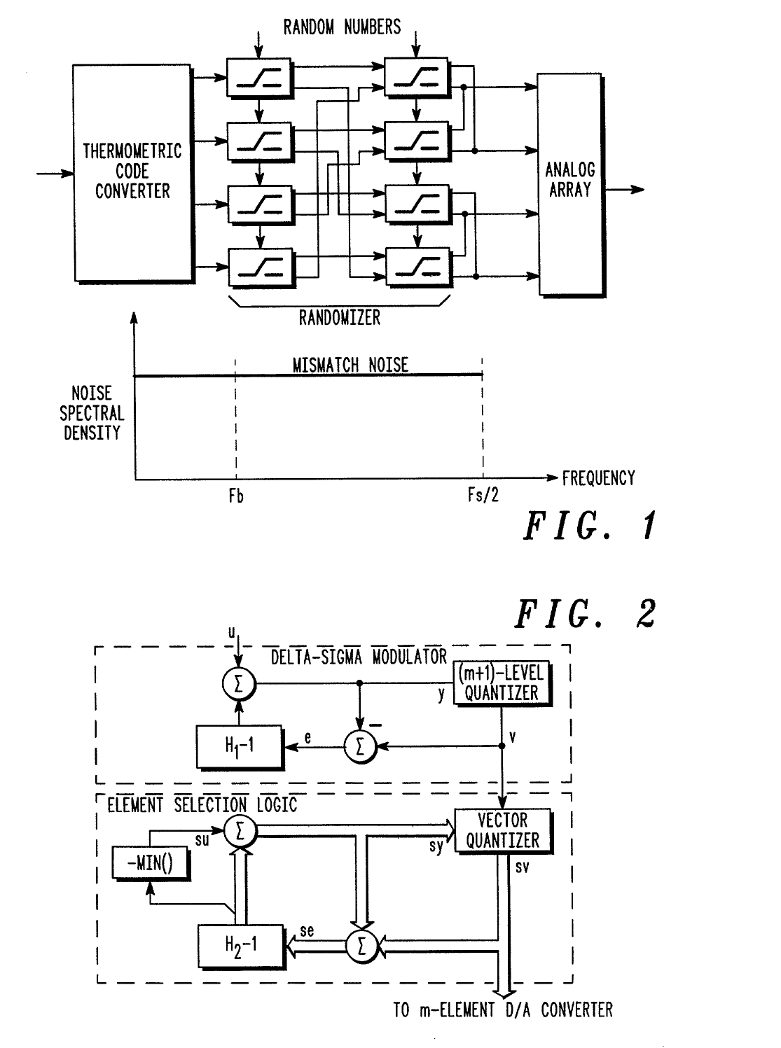

Detailed reference will now be made to FIGS. 1 and 2, the PRIOR ART, so as to assist in a better understanding of the invention. Reported simulation results indicate that element mismatch errors in a multibit DAC constructed from unit elements can be noise-shaped. A related work described the operating principle and showed that first-order noise-shaping was the result. Generalised approach and simulation results were shown for second-order and band pass noise-shaping.

FIG. 2 shows a block diagram of the proposed noise-shaped DAC convertor. The upper portion of the diagram depicts an ordinary delta-sigma modulator realized with the error-feedback structure, whereas the lower portion depicts the element selection logic. The two blocks are drawn in a manner which emphasises their similarity.

The modulator block accepts a finely quantized signal u and produces a coarsely quantized signal v. Denoting the quantiser error by e and adopting the convention that upper case variables represent Z-transform, the output of the modulator is:

V=U+H₁E

Thus, the output of the modulator is equal to its input plus an error term which, by suitable choice of H1 can be designed to have a small magnitude in a selected frequency range. Let us assume that v is quantised to one of m+1 integers in [0, m].

At each time step n, the element selection logic determines which v(n) of the m unit elements will be used to form the analogue output value. The output of the selection logic is sv(n), a 1×m vector, containing v(n) ones and m−v(n) zeros. Each unit element in the D/A convertor will be an analogue version of v(n) plus an error term due to element mismatch. The function of the selection logic is to ensure that the error term has a noise-shaped spectrum.

The selection vector sv is computed in a manner analogous to that which produces v, except that many signals in the selection logic circuitry (those shown with heavy lines) are vector valued. Based on the element usage requirement v, and on the contents of the vector sy, the vector quintiser sets certain elements of sv to one. The error of this quintisation operation se is fed back through an array of filters and added to the scalar valued selection logic input su to form to form subsequent samples of sy. Thus, the output of the selection logic is

(2)

SV=SU[1.1]+H₂(SE)

Let e_{d} be a (fixed) m×1 vector containing the difference between the value of each unit element in the D/A convertor and the mean of all the elements. Since the error between the actual output of the D/A convertor and its ideal output is

sv·e_{d}

and since the sum of all the components of ed is zero by definition, the D/A convertor error is

(3)

$$\begin{matrix}Error = ( SU [ 1 … 1 ] + {H}_{2} ( SE ) ) {e}_{d} \\ = SU \cdot 0 + {H}_{2} ( SE ) {e}_{d} \\ = {H}_{2} ( SE \cdot {e}_{d} )\end{matrix}$$

Eqn. 3 describes a static D/A convertor errors are shaped by the transfer function H2 provided, of course, that the se signal is bounded. This result is independent of the su input signal, the operation of the vector quantiser and the errors in the unit elements.

However, the su input sequence, the value of H2 and the quantiser algorithm affect the magnitude of the se signal. Since a vector quantiser of the form shown in FIG. 2 is more complex than a simple binary quintiser, providing the stability of the selection logic is a much more difficult problem than proving the stability of a delta-sigma modulator. The latter problem is unsolved and is usually addressed by simulation.

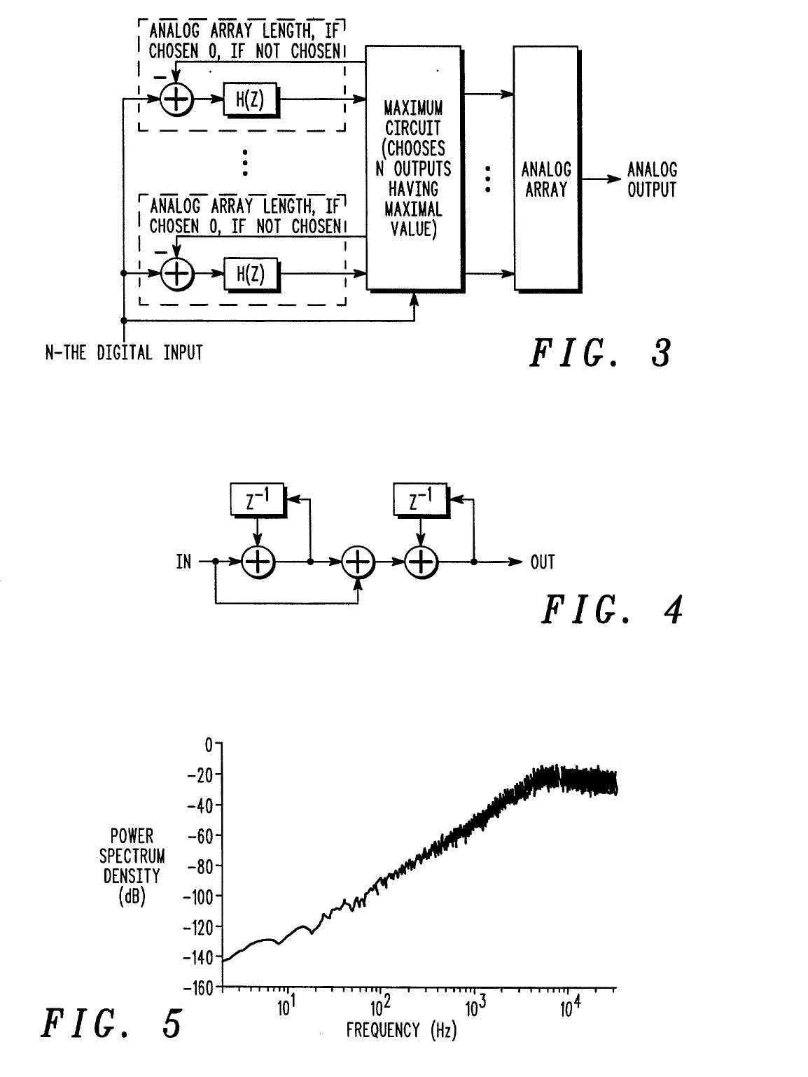

In the preferred embodiment described the proposed solution block diagram is given in FIG. 3. H (z) block defines a noise shaping properties. Each H (z) block obtains a digital input signal N represented as unsigned integer. The feedback state coming into H (z) depends on state of other H (z) blocks. Maximum circuit chooses N H (z) blocks having maximal output value. The chosen H (z) blocks get feedback equal to the number of elements in an analog array. This feedback reduces their value in such a way that in the next clock cycle a different group of H (z) blocks may be chosen.

Each H(z) block corresponds to one element in an analog array. H (z) block gets feedback when its corresponding element in the analog array is switched to add a transformed input signal to an output.

The order of H (z) block defines a noise shape order. If H (z) consists of two integrators, the noise shape becomes second-order.

An example of H(z) implementation for second-order shaping is shown diagrammatically in FIG. 4. The simulation results are shown on FIG. 5 for an analog array DAC having four elements, whose mismatch is 15%. In FIG. 5 we can see Power Spectrum Density (PSD) of current mismatch noise using proposed Dynamic Element Matching method. Second-order noise shaping is clearly seen. Higher-order noise shaping, such as cubic or quartic noise shaping, is also possible.

A general linear model, describing a single-quantizer □□modulator is shown in FIG. 6, which is a general block diagram for a single-quantizer □□modulator. The modulator is split into a linear block (the loop filter) and a non-linear block (the quantizer). The linear block has arbitrary transfer functions from its two inputs U and V to its single output Y. These transfer functions have been labelled for convenience as

$$\begin{matrix}{L}_{0} ( z ) = \frac{G ( z )}{H ( z )} \\ and & ( 4 ) \\ {L}_{1} ( z ) = \frac{[ H ( z ) - 1 ]}{H ( z )} & ( 5 )\end{matrix}$$

G(z) is called a signal transfer function (STF) and H(z) is called a noise transfer function (NTF).

With these assignments, the output of the linear block is

(6)

Y(z)=L₀(z)U(z)+L₁(z)V(z)

By defining the error signal e as E(z)=V(z)−Y(z), Eqn. (6) can be re-arranged to give the familiar formula for the output of the modulator in terms of its input and the error signal:

(7)

V(z)=G(z)U(z)+H(z)E(z)

We shall use Eqn. 7 to describe second-order delta-sigma modulator, depicted in FIG. 7, which presents a generalized model of second-order Sigma-Delta modulator.

The signal and noise transfer functions are

$$G ( z ) = \frac{z}{{z}^{2} + ( - 1 + α + β + γ ) z + ( 1 - β - γ )} \\ H ( z ) = \frac{{z}^{2} + ( - 2 + α + b ) z + ( 1 - β ) }{{z}^{2} + ( - 1 + α + β + γ ) z + ( 1 - β - γ )} \qquad ( 8 )$$

The system is described by the following signal and noise transfer functions and differs from the second order modulator shown in FIG. 8:

$$G ( z ) = \frac{z}{{z}^{2} + ( - 2 + α + β + γ n + n ) z + ( 1 - β - γ n )} \\ H ( z ) = \frac{{z}^{2} + ( - 2 + α + β ) z + ( 1 - β )}{{z}^{2} + ( - 2 + α + β + γ n + n ) z + ( 1 - β - γ n )} \qquad ( 9 )$$

Assuming α=β=0, then the system obtained is described by:

$$\begin{matrix}G ( z ) = \frac{z}{{z}^{2} + ( - 2 + γ n + n ) z + ( 1 - γ n )} \\ = \frac{{z}^{- 1}}{1 + ( - 2 + γ n + n ) {z}^{- 1} + ( 1 - γ n ) {z}^{- 2}} & ( 10 ) \\ H ( z ) = \frac{{z}^{2} - 2 z + 1}{{z}^{2} + ( - 2 + γ n + n ) z + ( 1 - γ n )} \\ = \frac{{( 1 - {z}^{- 1} )}^{2}}{1 + ( - 2 + γ n + n ) {z}^{- 1} + ( 1 - γ n ) {z}^{- 2}} & ( 11 )\end{matrix}$$

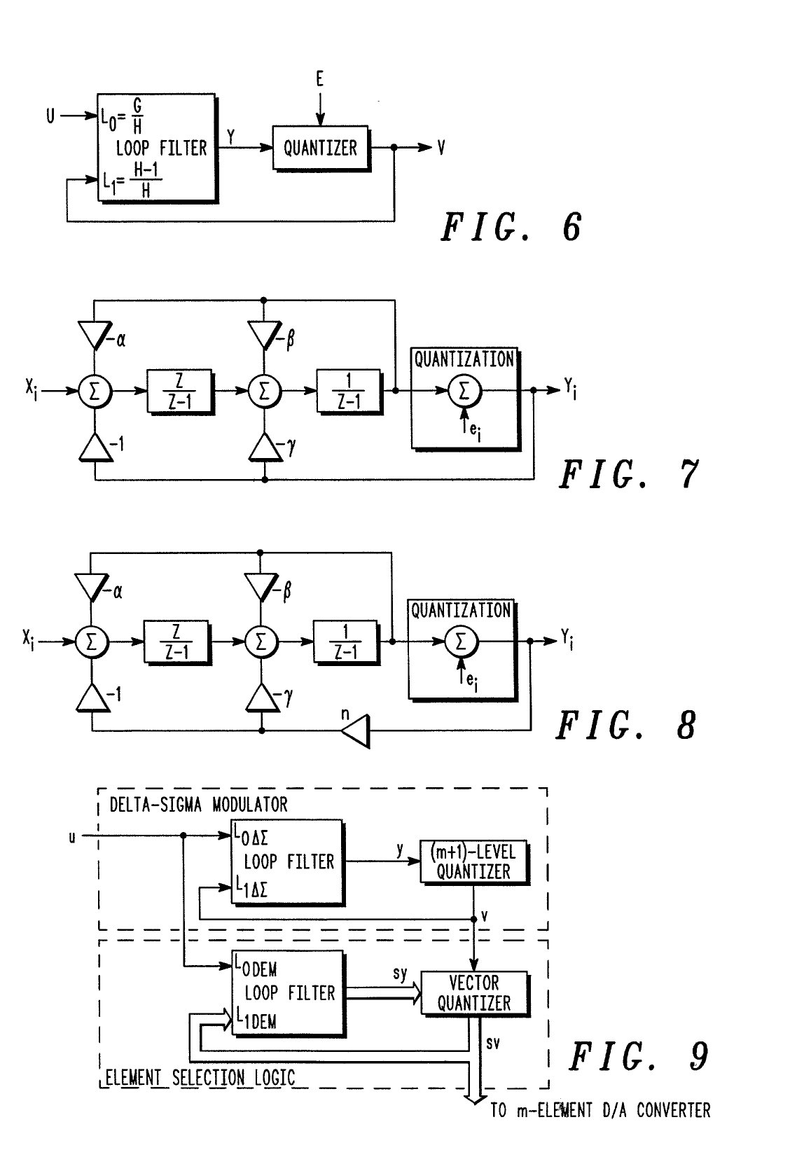

There is therefore disclosed an architecture for a noise-shaped, multi-bit DAC, where element selection logic is realized, using architecture described by Eqns. 10 and 11. The system diagram is depicted in FIG. 9

The invention has been described by way of exemplary embodiments only. It will be appreciated that variation to the embodiments described herein may be made, without departing from the scope of the invention.

1. An apparatus for dynamic element matching comprising: means for receiving an input, means for applying a transfer function for transforming the input to a transformed value; a store containing a plurality of predetermined values which are accessible in digital form; means for retrieving one or more of the stored values in accordance with an instruction derived from the transformed value; an adder for summing retrieved stored values and providing, in digital form, an output of the sum of said values; means for comparing said sum with the transformed value so that an error signal is derived, wherein said error signal is used to correct any signal mismatch.

2. Apparatus according to claim 1 wherein means is provided to modify the order of the transfer function so that an optimisation of element matching is achieved.

3. Apparatus according to claim 2 wherein the means for modifying the order of the transfer function includes a component for performing a logical operation.

4. Apparatus according to claim 3 wherein the component is an inverter.

5. Apparatus according to claim 3 wherein the component is an AND gate.

6. Apparatus according to claim 1 which is incorporated in a Digital-to-Analog Converter.

7. Apparatus according to claim 1 which is incorporated in an Analog-to-Digital Converter.

8. A Digital-to-Analog Converter according to claim 6 included in telecommunication equipment.

9. An Analog-to-Digital Converter according to claim 7 included in telecommunication equipment.

10. A method for dynamic element matching comprising: the steps of receiving an input, applying a transfer function which transforms the input to a transformed value; accessing a store containing a plurality of predetermined values and retrieving one or more of the stored values in digital form, in accordance with an instruction derived from the transformed value; summing retrieved stored values and providing, in digital form, an output of the sum; comparing said sum with the transformed value so that an error signal is derived; and using said error signal to correct signal mismatch.
